(19) United States
(12) Patent Application Publication
(10) Pub. No.: US 2021/0407397 A1
(43) Pub. Date: Dec. 30, 2021

(54) SHIFT REGISTER AND SHIFT REGISTER CIRCUIT THEREOF, DISPLAY PANEL AND ELECTRONIC DEVICE

(71) Applicant: Shanghai Tianma AM-OLED Co.,Ltd., Shanghai (CN)

(72) Inventors: Mengmeng ZHANG, Shanghai (CN); Yue LI, Shanghai (CN); Xingyao ZHOU, Shanghai (CN); Haojie XU, Shanghai (CN)

(21) Appl. No.: 17/001,852

(22) Filed: Aug. 25, 2020

(30) Foreign Application Priority Data
Jun. 30, 2020 (CN) 202010622535.8

(51) Int. Cl. G09G 3/3225; G11C 19/28

(52) U.S. Cl. CPC G09G 3/3225; G09G 2310/08; G09G 2310/0286; G11C 19/28

(57) ABSTRACT

A shift register, a shift register circuit, a display panel, and an electronic device are provided. The shift register includes an input circuit, a trigger output terminal, and an invert output terminal. A shift signal input terminal of the input circuit is electrically connected to a shift signal output terminal of an upper-level shift register. A shift signal output terminal of the trigger output circuit is electrically connected to a shift circuit input terminal of a lower-level shift register. The input circuit is configured to control potentials of a first node and a second note of the shift register to drive the trigger output circuit to output a first voltage signal to a first scan line and to output a second voltage signal to a second scan line. The first voltage signal is different from the second voltage signal.

### CROSS-REFERENCES TO RELATED APPLICATIONS

This application claims priority of Chinese Patent Application No. 202010622535.8, filed on Jun. 30, 2020, the entire contents of which are hereby incorporated by reference.

### FIELD OF THE DISCLOSURE

The present disclosure generally relates to the field of shift registers and, more particularly, relates to a shift register and a shift register circuit, a display panel and an electronic device.

### BACKGROUND

Shift registers are usually used to drive pixel circuits. Transistors of pixel circuits are mostly prepared by a low-temperature polysilicon (LTPS) technology, and their leakage currents are relatively large, which cannot meet requirements of the image quality of a low-frequency display. To achieve the low frequency display, the switch transistors in the pixel circuits can be replaced with N-type transistors. The N-type transistor is turned on by a high-level scan signal, and the PMOS transistor is turned on by a low-level scan signal.

However, the shift register circuit mainly outputs low-level scan signals, and cannot output high-level signals and low-level signals at the same time, resulting in the inability to drive pixel circuits suitable for the low-frequency display. The disclosed shift register, shift register circuit, display panel and electronic device are directed to solve one or more problems set forth above and other problems in the art.

### BRIEF SUMMARY OF THE DISCLOSURE

One aspect of the present disclosure provides a shift register. The shift register includes an input circuit. The input circuit includes a first control terminal electrically connected to a first clock signal terminal of the shift register; a second control terminal electrically connected to a second clock signal terminal of the shift register, wherein a shift signal input terminal of the shift register is electrically connected to a shift signal output terminal of an upper-level shift register; a first signal input terminal electrically connected to a first power source terminal of the shift register; a second signal input terminal electrically connected to a second power source terminal of the shift register; and a first output terminal electrically connected to a first node and a second output terminal electrically connected to a second node, to control potentials of the first node and the second node. The shift register also include a trigger output circuit, including a third signal input terminal electrically connected to the first power source terminal, a fourth signal input terminal electrically connected to the first clock signal terminal, a third control terminal electrically connected to the first node, a fourth control terminal electrically connected to the second node, and a shift signal output terminal electrically connected to a third node, a first scan line and a shift signal input terminal of a lower-level shift register, respectively. Further, the shift register includes a revert output circuit, including a fifth control terminal electrically connected to the third node, a sixth control terminal electrically connected to a third clock terminal, a fifth signal input terminal electrically connected to the first power source terminal, a sixth signal input terminal electrically connected to the second power source terminal, and a scan signal output terminal electrically connected to a second scan line. The input circuit is configured to control the potentials of the first node and the second node to drive the trigger output terminal to output a first voltage signal to the first scan line and to drive the invert output circuit to output a second voltage signal to the second scan line; and the first voltage signal is different from the second voltage signal.

Another aspect of the present disclosure provides a shift register circuit. The shift register circuit includes a plurality of multi-level cascaded shift registers. Each shift register includes an input circuit. The input circuit includes a first control terminal electrically connected to a first clock signal terminal of the shift register; a second control terminal electrically connected to a second clock signal terminal of the shift register, wherein a shift signal input terminal of the shift register is electrically connected to a shift signal output terminal of an upper-level shift register; a first signal input terminal electrically connected to a first power source terminal of the shift register; a second signal input terminal electrically connected to a second power source terminal of the shift register; and a first output terminal electrically connected to a first node and a second output terminal electrically connected to a second node, to control potentials of the first node and the second node. The shift register also include a trigger output circuit, including a third signal input terminal electrically connected to the first power source terminal, a fourth signal input terminal electrically connected to the first clock signal terminal, a third control terminal electrically connected to the first node, a fourth control terminal electrically connected to the second node, and a shift signal output terminal electrically connected to a third node, a first scan line and a shift signal input terminal of a lower-level shift register, respectively. Further, the shift register includes a revert output circuit, including a fifth control terminal electrically connected to the third node, a sixth control terminal electrically connected to a third clock terminal, a fifth signal input terminal electrically connected to the first power source terminal, a sixth signal input terminal electrically connected to the second power source terminal, and a scan signal output terminal electrically connected to a second scan line. The input circuit is configured to control the potentials of the first node and the second node to drive the trigger output terminal to output a first voltage signal to the first scan line and to drive the invert output circuit to output a second voltage signal to the second scan line; and the first voltage signal is different from the second voltage signal.

Another aspect of the present disclosure provides a display panel. The display panel includes a display area and a non-display area. The display area includes a plurality row of pixel circuits; the non-display area includes a plurality of multi-level cascaded shift registers; one level shift register is configured to drive at least one row of the plurality row of pixel circuits; the plurality of multi-level cascaded shift registers includes a shift signal output terminal and a scan signal output terminal; the plurality row of pixel circuits includes a first scan terminal and a second scan terminal; the shift signal output terminal of the plurality of multi-level cascaded shift registers is connected to the first scan terminal of a corresponding row of pixel circuits by a first scan line; and the scan signal output terminal of the plurality of multi-level cascaded shift registers is connected to the second scan terminal of a corresponding row of pixel circuits by a second scan line.

Another aspect of the present disclosure provides an electronic device including a disclosed display panel.

Other aspects of the present disclosure can be understood by those skilled in the art in light of the description, the claims, and the drawings of the present disclosure.

### BRIEF DESCRIPTION OF THE DRAWINGS

To explain the embodiments of the present disclosure or the technical solutions in the prior art more clearly, the following will briefly introduce the drawings that need to be used in the description of the present embodiments or the prior art. Obviously, although the drawings in the following description are some specific embodiments of the present disclosure, for those skilled in the art, the basic concepts of the device structure, driving method and manufacturing method disclosed and suggested in the various embodiments of the present disclosure can be expanded and extended to other structures and drawings, without doubt, such as extension and modification should fall within the scope of the claims of the present disclosure.

The following drawings are incorporated in and constitute a part of the specification, illustrating embodiments of the present disclosure, and together with the detailed descriptions serve to explain the mechanism of the present disclosure.

FIG. 1 illustrates an exemplary shift register consistent with various disclosed embodiments of the present disclosure;

FIG. 2 illustrates a time sequence of the shift register in FIG. 1;

FIG. 3 illustrates a circuit diagram of a first time period of an exemplary shift register consistent with various disclosed embodiments of the present disclosure;

FIG. 4 illustrates a circuit diagram of a second time period of an exemplary shift register consistent with various disclosed embodiments of the present disclosure;

FIG. 5 illustrates a circuit diagram of a third time period of an exemplary shift register consistent with various disclosed embodiments of the present disclosure;

FIG. 6 illustrates a circuit diagram of a fourth time period of an exemplary shift register consistent with various disclosed embodiments of the present disclosure;

FIG. 7 illustrates a circuit diagram of a fifth time period of an exemplary shift register consistent with various disclosed embodiments of the present disclosure;

FIG. 8 illustrates a circuit diagram of a sixth time period of an exemplary shift register consistent with various disclosed embodiments of the present disclosure;

FIG. 9 illustrates another exemplary shift register consistent with various disclosed embodiments of the present disclosure;

FIG. 10 illustrates an exemplary shift register circuit consistent with various disclosed embodiments of the present disclosure;

FIG. 11 illustrates another exemplary shift register circuit consistent with various disclosed embodiments of the present disclosure;

FIG. 12 illustrates an exemplary display panel consistent with various disclosed embodiments of the present disclosure;

FIG. 13 illustrates a pixel circuit; and

FIG. 14 illustrates an exemplary electronic device consistent with various disclosed embodiments of the present disclosure.

### DETAILED DESCRIPTION

Reference will now be made in detail to exemplary embodiments of the disclosure, which are illustrated in the accompanying drawings. Hereinafter, embodiments consistent with the disclosure will be described with reference to drawings. Wherever possible, the same reference numbers will be used throughout the drawings to refer to the same or like parts. It is apparent that the described embodiments are some but not all the embodiments of the present disclosure. Based on the disclosed embodiments, persons of ordinary skill in the art may derive other embodiments consistent with the present disclosure, all of which are within the scope of the present disclosure. Further, in the present disclosure, the disclosed embodiments and the features of the disclosed embodiments may be combined when there are no conflicts.

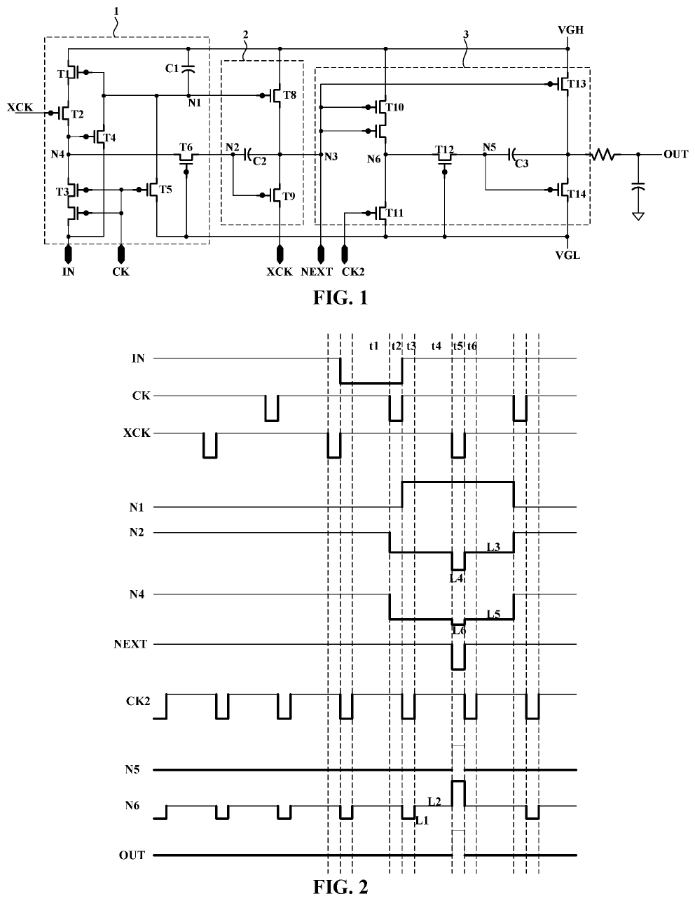

The present disclosure provides a shift register, a shift register circuit, a display panel, and an electronic device. FIG. 1 illustrates an exemplary shift register consistent with various disclosed embodiments of the present disclosure.

As shown in FIG. 1, the shift register provided in present disclosure may include an input circuit 1, a trigger output circuit 2, and an invert output circuit 3. The first control terminal of the input circuit 1 may be electrically connected to a first clock signal terminal XCK, and the second control terminal of the input circuit 1 may be electrically connected to a second clock signal terminal CK. The shift signal input terminal IN may be electrically connected to the shift signal output terminal of an upper-level shift register. The first signal input terminal may be electrically connected to a first power source terminal, and the second signal input terminal may be electrically connected to a second power source terminal. The first output terminal may be electrically connected to a first node N1, and the second output terminal may be electrically connected to a second node N2 to control the potentials of the first node N1 and the second node N2. The third signal input terminal of the trigger output circuit 2 may be electrically connected to the first power source terminal, and the fourth signal input terminal of the trigger output circuit 2 may be electrically connected to the first clock signal terminal XCK. The third control terminal of the trigger output circuit 2 may be electrically connected to the first node N1, and the fourth control terminal of the trigger output circuit 2 may be electrically connected to the second node N2. The shift signal output terminal NEXT of the trigger output circuit 2 may be electrically connected to a third node N3. The first scan line may be electrically connected to the shift signal input terminal of a lower-level shift register. The fifth control terminal of the invert output circuit 3 may be electrically connected to the third node N3. The sixth control terminal of the invert output circuit 3 may be electrically connected to a third clock signal terminal CK2. The fifth signal input terminal may be electrically connected to the first power source terminal. The sixth signal input terminal may be electrically connected to the second power source terminal. The scan signal output terminal OUT may be electrically connected to a second scan line. The input circuit 1 may be configured to control the potentials of the first node N1 and the second node N2 to drive the trigger output circuit 2 to output a first voltage signal to the first scan line, and to drive the invert output circuit 3 to output a second voltage signal to the second scan line. The first voltage signal may be different from the second voltage signal.

In such a configuration, the input circuit 1 may receive the signal of the first clock signal terminal XCK, and may also receive the signal of the second clock signal terminal CK. Under the control of the signal of the first clock signal terminal XCK and the signal of the second clock signal terminal CK, according to the signal of the shift signal input terminal IN, the signal of the first power source terminal and the signal of the second power source terminal, the potential of the first node N1, the potential of the second node N2 and the potential of the fourth stage in the circuit may be controlled.

Further, the trigger output circuit 2 may receive the signal of the first node N1 and the second node N2. Under the control of the signal of the first node N1 and the signal of the second node N2, the potential of the third node N3 may be controlled according to the signal of the first power source terminal and the signal of the first clock signal terminal XCK. Thus, the pixel circuit may be driven through the first scan line electrically connected thereof, and that whether to trigger the lower-level shift register to work may also be controlled.

The invert output circuit 3 may receive the signal of the third node N3, and may also receive the signal of the third clock signal terminal CK2. Under the control of the signal of the third node N3 and the signal of the third clock signal terminal CK2, the scan signal output terminal OUT may be controlled according to the signal of the first power source terminal and the signal of the second power source terminal. Thus, the pixel circuit may be driven through the second scan line electrically thereof.

In one embodiment, the first power source terminal may be a high-level signal terminal VGH, and the second power source terminal may be a low-level signal terminal VGL. Under the control of the signal of the third node N3 and the signal of the third clock signal terminal CK2, the invert output circuit 3 may select to turn on the transmission path between the high-level signal terminal VGH and the scan signal output terminal OUT to allow the scan signal output terminal OUT to output a high-level signal to the second scan line. Or, the invert output circuit 3 may select to turn on the transmission path between the low-level signal terminal VGL and the scan signal output terminal OUT to allow the scan signal output terminal OUT to output a low-level signal to the second scan line. The phase of the first voltage signal and the phase of the second voltage signal may be opposite.

Thus, in one embodiment, in the first output period, the input circuit 1 may control the potentials of the first node N1 and the second node N2 to drive the trigger output circuit 2 to output a low-level signal to the first scan line, and may also drive the invert output circuit 3 to output a high-level signal to the second scan line. In the second output stage, the input circuit 1 may control the potentials of the first node N1 and the second node N2 to drive the trigger output circuit 2 to output a high-level signal to the first scan line, and at the same time, may also drive the invert output circuit 3 to output a low-level signal to the second scan line.

The shift register provided in the present disclosure may be able to transmit two different voltage signals at the same time during each output period. In particular, the disclosed shift register may be able to transmit a low-level signal or a high-level signal at same time. Thus, the shift register may be suitable for driving any pixel circuit that receives two scan signals with different phases.

The above is the overall structure of the shift register provided by the present disclosure. The specific structure and working principle of the shift register will be explained in the following several embodiments.

In one embodiment, as shown in FIG. 1, the input circuit 1 may include a first switch T1, a second switch T2, a third switch T3, and a fourth switch T4, a fifth switch T5, a sixth switch T6, and a first capacitor C1. The control terminal of the first switch T1 may be electrically connected to the first node N1. The input terminal of the first switch T1 may be electrically connected to the first power source terminal VGH, and the output terminal of the first switch T1 may be electrically connected to the input terminal of the second switch T2. The control terminal of the second switch T2 may be electrically connected to the first clock signal terminal XCK, and the output terminal of the second switch T2 may be electrically connected to the control terminal of the fourth switch T4. The input terminal of the fourth switch T4 may be electrically connected to the shift signal input terminal IN, and the output terminal of the fourth switch T4 may be electrically connected to the first node N1. The control terminals of the third switch T3 and the fifth switch T5 may be electrically connected to the second clock signal terminal CK. The output terminal of the third switch T3 may be electrically connected to the control terminal of the fourth switch T4, and the input terminal of the third switch T3 may be electrically connected to the shift signal input terminal IN. The input terminal of the fifth switch T5 may be electrically connected to the second power source terminal VGL and the output terminal of the fifth switch T5 may be electrically connected to the first node N1. The control terminal of the sixth switch T6 may be electrically connected to the second power source terminal VGL, the input terminal of the sixth switch T6 may be electrically connected to the output terminal of the third switch T3, and the output terminal of the sixth switch T6 may be electrically connected to the second node N2. The first capacitor C1 may be coupled between the first power source terminal VGH and the first node N1. In one embodiment, the third switch T3 may be a double-gate transistor, and the output terminal of the third switch T3 may be set as the fourth node N4.

Further, as shown in FIG. 1, in one embodiment, the trigger output circuit 2 may include an eighth switch T8, a ninth switch T9 and a second capacitor C2. The control terminal of the eighth switch T8 may be electrically connected to the first node N1, the input terminal of the eighth switch T8 may be electrically connected to the first power source terminal VGH, and the output terminal of the eighth switch T8 may be electrically connected to the shift signal output terminal NEXT. The control terminal of the ninth switch T9 may be electrically connected to the second node N2, the input terminal of the ninth switch T9 may be electrically connected to the first clock signal terminal XCK, and the output terminal of the ninth switch T9 may be electrically connected to the shift signal output terminal NEXT. The second capacitor C2 may be coupled between the second node N2 and the shift signal output terminal NEXT. In such a configuration, the shift signal output terminal NEXT of the shift register of this level may be electrically connected to the third node N3 to control the inverting output circuit 3, and may also be electrically connected to the first scan line to transmit the shift output signal to the first scan line. Further, the shift signal output terminal NEXT may also be electrically connected to the shift signal input terminal of a next level shift register to control the operation of the next level shift register.

Further, as shown in FIG. 1, in one embodiment, the invert output circuit 3 may include a tenth switch T10, an eleventh switch T11, a twelfth switch T12, a thirteenth switch T13, a fourteenth switch T14, and a third capacitor C3. The control terminal of the tenth switch T10 may be electrically connected to the third node N3, and the input terminal of the tenth switch T10 may be electrically connected to the first power source terminal VGH. The output terminal of the tenth switch T10 may be electrically connected to the input terminal of the twelfth switch T12. The control terminal of the eleventh switch T11 may be electrically connected to the third clock signal terminal CK2, the input terminal of the eleventh switch T11 may be electrically connected to the second power source terminal VGL, and the output terminal of the eleventh switch T11 may be electrically connected to the input terminal of the twelfth switch T12. The control terminal of the twelfth switch T12 may be electrically connected to the second power source terminal VGL, and the output terminal of the twelfth switch T12 may be electrically connected to the control terminal of the fourteenth switch T14. The input terminal of the fourteenth switch T14 may be electrically connected to the second power source terminal VGL, and the output terminal of the fourteenth switch T14 may be electrically connected to the scan signal output terminal OUT. The control terminal of the thirteenth switch T13 may be electrically connected to the third node N3, the input terminal of the thirteenth switch T13 may be electrically connected to the first power source terminal VGH, and the output terminal of the thirteenth switch T13 may be electrically connected to the scan signal output terminal OUT. The third capacitor C3 may be coupled between the control terminal of the fourteenth switch T14 and the scan signal output terminal OUT. In one embodiment, the control terminal of the fourteenth switch T14 may be set as the fifth node N5, and the output terminal of the eleventh switch T11 may be set as the sixth node N6.

Each switch in the shift register illustrated in FIG. 1 may be a PMOS transistor.

In some embodiments, each switch in the shift register may be an NMOS transistor.

FIG. 2 illustrates an exemplary time sequence control diagram of the shift register shown in FIG. 1 consistent with various disclosed embodiments of the present disclosure.

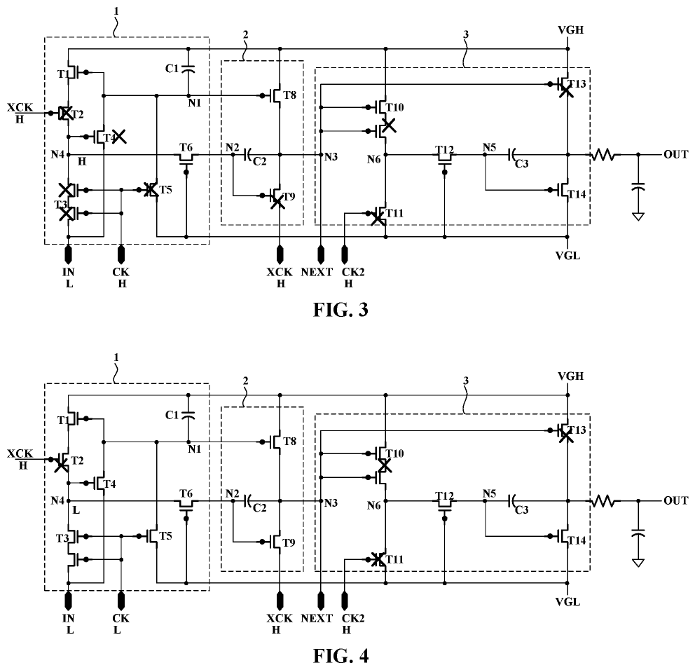

FIG. 3 is a circuit diagram of an exemplary shift register in a first time period consistent with various disclosed embodiments of the present disclosure. As shown in FIG. 2 and FIG. 3, in the first time period t1, the shift signal input terminal IN may receive a low-level signal, the second clock terminal CK may receive a high-level signal, the first clock signal terminal XCK may receive a high-level signal, the third clock signal terminal CK2 may receive a high-level signal, and the fourth node N4 may be stabilized at a high-level.

During the first time period t1, the second switch T2, the third switch T3, the fourth switch T4, and the fifth switch T5 of the input circuit 1 may be turned off, and the first switch T1 and the sixth switch T6 may be turned on. The second node N2 may have the same potential as the fourth node N4, and may both be at a high-level. The first capacitor C1 may be set to avoid the first node N1 being suspended, and the first node N1 may be stabilized at a low-level. The first node N1 may be at the low-level and the second node N2 may be at the high-level. The ninth switch T9 in the trigger output circuit 2 may be triggered to be turned off. The eighth switch T8 may be turned on. The second capacitor C2 may stabilize the third node N3 to be at a high-level, and the shift signal output terminal NEXT may output the high-level signal. The third node N3 may be at the high-level. The tenth switch T10, the eleventh switch T11 and the thirteenth switch T13 may be turned off. The twelfth switch T12 may be turned on, and the fifth node N5 and the sixth node N6 may have a same potential. The third capacitor C3 may prevent the fifth node N5 from being suspended, and may stabilize the fifth node N5 to be at a low-level. The fourteenth switch T14 may be turned on, and the scan signal output terminal OUT may be pulled down to the low-level.

FIG. 4 is a circuit diagram of an exemplary shift register in a second time period consistent with various disclosed embodiments of the present disclosure. As shown in FIG. 4, in the second time period t2, the shift signal input terminal IN may receive a low-level signal; and the second clock signal terminal CK may receive a low-level signal. The first clock signal terminal XCK may receive a high-level signal, and the third clock signal terminal CK2 may receive a high-level signal.

During the second time period t2, the second switch T2 of the input circuit 1 may be turned off. The first switch T1, the third switch T3, the fourth switch T4, and the fifth switch T5 and the sixth switch T6 of the input circuit 1 may be turned on. The fourth node N4 may be pulled down to a low-level. In particular, the second node N2 may be at the low-level. The first node N1 may be stabilized at the low-level. Because the first node N1 may be at the low-level and the second node N2 may be at the low-level, the eighth switch T8 and the ninth switch T9 of the trigger output circuit 2 may be triggered to be turned on. The third node N3 may be stabilized at a high-level. The shift signal output terminal NEXT may output a high-level signal. The third node N3 may be at the high-level. The tenth switch T10, the eleventh switch T11 and the thirteenth switch T13 may be turned off, and the twelfth switch T12 may be turned on. The fifth node N5 and the sixth node N6 may have a same potential. The third capacitor C3 may prevent the fifth node N5 from being suspended; and the fifth node N5 may be stabilized at the low-level. The fourteenth switch T14 may be turned on; and the scan signal output terminal OUT may be pulled down to a low-level.

FIG. 5 is a circuit diagram of an exemplary shift register during a third time period consistent with various disclosed embodiments of the present disclosure. As shown in FIG. 5, during the third time period t3, the shift signal input terminal IN may receive a high-level signal; and the second clock signal terminal CK may receive a high-level signal. The first clock signal terminal XCK may receive a high-level signal, and the third clock signal terminal CK2 may receive a low-level signal.

During the third time period t3, the first switch T1, the second switch T2, the third switch T3, and the fifth switch T5 the input circuit 1 may be turned off. The fourth node N4 may be at a low-level. The fourth switch T4 may be turned on, and the sixth switch may be turned on. The second node N2 and the fourth node N4 may be at a same potential, and may both be at the low-level. The first node N1 and the shift signal input terminal may be at the same potential; and may be stabilized at the high-level by the first capacitor C1. Because the first node N1 may be at the high-level and the second node N2 may be at the low-level, the ninth switch T9 in the trigger output circuit 2 may be triggered to be turned on and the eighth switch T8 may be triggered to be turned off. The first clock signal terminal XCK may charge the second capacitor C2 to stabilize the third node N3 to be at a high-level. The shift signal output terminal NEXT may output the high-level signal. The third node N3 may be at the high-level. The tenth switch T10 and the thirteenth switch T13 may be turned off. The eleventh switch T11 and the twelfth switch T12 may be turned on. The sixth node N6 may be further pulled-down to L1. The fifth node N5 may be pulled-down to the low-level by the third capacitor C3. The fourteenth switch T14 may be turned on; and the scan signal output terminal OUT may be pulled down to the low-level.

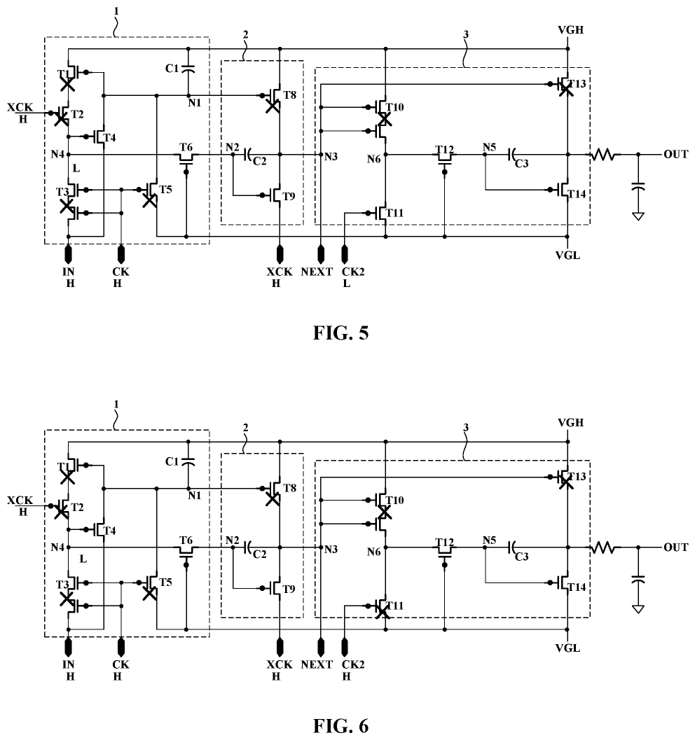

FIG. 6 is a circuit diagram of an exemplary shift register during a fourth time period consistent with various disclosed embodiments of the present disclosure. As shown in FIG. 6, during the fourth time period t4, the shift signal input terminal IN may receive a high-level signal; and the second clock signal terminal CK may receive a high-level signal. The first clock signal terminal XCK may receive a high-level signal, and the third clock signal terminal CK2 may receive a high-level signal.

During the fourth time period t4, the first switch T1, the second switch T2, the third switch T3, and the fifth switch T5 of the input circuit 1 may be turned off. The fourth node N4 may be at a low-level. The sixth switch T6 may be turned on. The second node N2 and the fourth node N4 may be at a same potential, and may both be at the low-level. The first node N1 and the shift signal input terminal IN may be at the same potential; and may be stabilized at the high-level by the first capacitor C1. Because the first node N1 may be at the high-level and the second node N2 may be at the low-level, the ninth switch T9 in the trigger output circuit 2 may be triggered to be turned on and the eighth switch T8 may be triggered to be turned off. The first clock signal terminal XCK may charge the second capacitor C2 to stabilize the third node N3 to be at a high-level. The shift signal output terminal NEXT may output the high-level signal. Because the third node N3 may be at the high-level, the tenth switch T10, the eleventh switch T11 and the thirteenth switch T13 may be turned off. The twelfth switch T12 may be turned on. The fifth node N5 may be pulled down to the low-level by the third capacitor C3. The potential of the fifth node N5 may be equal to the potential of the sixth node N6 to pull down the sixth node N6 to be at a low-level L2. The fourteenth switch T14 may be turned on; and the scan signal output terminal OUT may be pulled down to the low-level.

FIG. 7 is a circuit diagram of an exemplary shift register during a fifth time period consistent with various disclosed embodiments of the present disclosure. As shown in FIG. 7, during the fifth time period t5, the shift signal input terminal IN may receive a high-level signal; and the second clock signal terminal CK may receive a high-level signal. The first clock signal terminal XCK may receive a low-level signal, and the third clock signal terminal CK2 may receive a high-level signal.

During the fifth time period t5, the first switch T1, the third switch T3, and the fifth switch T5 of the input circuit 1 may be turned off. The fourth node N4 may be at a low-level. The second switch T2 and the sixth switch T6 may be turned on. The second node N2 and the fourth node N4 may have a same potential, may be both at the low-level. The first node N1 and the shift signal input terminal IN may be at the same potential; and may be stabilized at the high-level by the first capacitor C1. Because the first node N1 may be at the high-level, and the second node N2 and the fourth node N4 may be at the low-level, the ninth switch T9 of the trigger output circuit 2 may be triggered to be turned on and the eighth switch T8 may be triggered to be turned off. The third node N3 may be discharged. The second node N2 may be pulled down from the potential L3 to a lower potential L4 under the function of the second capacitor C; and the fourth node N4 may be pulled down to a lower potential L6 by the second node N2. The pulled-down scale of the second node N2 may be greater than the pull-down scale of the fourth node N4. In particular, |L3−L4|>|L5−L6|. The discharge of the third node N3 may cause the shift signal output terminal NEXT to output a low-level signal. Because the third node N3 may be at the low-level, the tenth switch T10 and the thirteenth switch T13 may be turned on. The fifth node N5 and the sixth node N6 may be pulled up as the high-level VGH. The fourteenth switch T14 may be turned off; and the scan signal output terminal OUT may output a high-level signal.

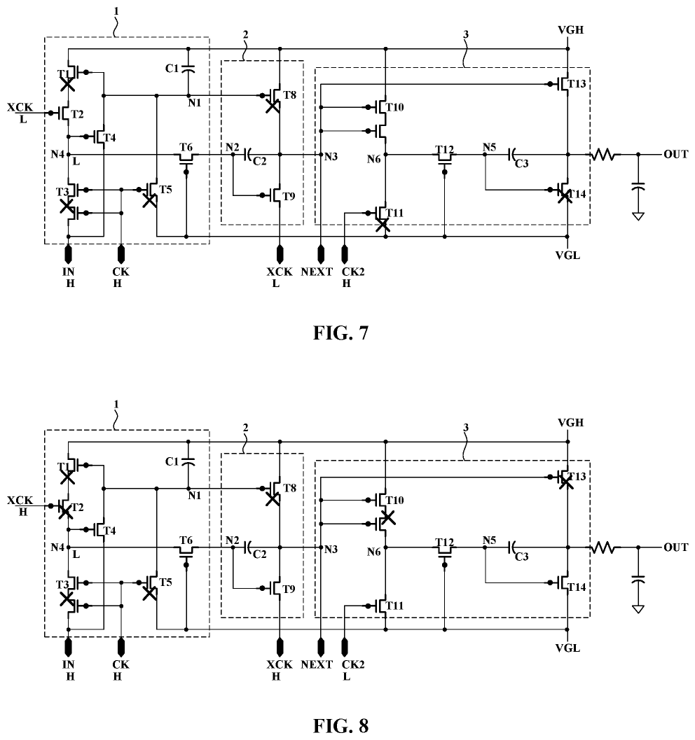

FIG. 8 is a circuit diagram of an exemplary shift register during a sixth time period consistent with various disclosed embodiments of the present disclosure. As shown in FIG. 8, during the sixth time period t6, the shift signal input terminal IN may receive a high-level signal; and the second clock signal terminal CK may receive a high-level signal. The first clock signal terminal XCK may receive a high-level signal, and the third clock signal terminal CK2 may receive a low-level signal.

During the sixth time period t6, the first switch T1, the second switch T2, the third switch T3, and the fifth switch T5 of the input circuit 1 may be turned off. The fourth node N4 may be at a low-level. The fourth switch T4 and the sixth switch T6 may be turned on. The second node N2 may be at a low-level. The first node N1 and the shift signal input terminal IN may be at the same potential; and may be stabilized at the high-level by the first capacitor C1. Because the first node N1 may be at the high-level, and the second node N2 and the fourth node N4 may be at the low-level, the ninth switch T9 in the trigger output circuit 2 may be triggered to be turned on, and the eighth switch T8 may be triggered to be turned off. The third node N3 may be charged. The second node N2 may be pulled-up to L3 under the function of the second capacitor C2, and the fourth node N4 may be pulled-up L5 by the second node N2. The third node N3 may be charged to cause the shift signal output terminal NEXT to output a high-level signal. Because the third node N3 may be at the high-level, the tenth switch T10 and the thirteenth switch T13 may be turned off. The eleventh switch T11 and the twelfth switch T12 may be turned on. The fifth node N5 and the sixth node N6 may be discharged at the low-level. The fourteenth switch T14 may be turned on; and the scan signal output terminal OUT may output a low-level signal VGL.

In one embodiment, as shown in the fifth time period, when the output signal of the shift signal output terminal NEXT of the shift register is at the low-level, the output signal of the scan signal output terminal OUT may be at the high-level. Thus, the shift register may be able to drive the pixel circuit with two different phases of scanning signal terminals. In other time periods, when the output signal of the shift signal output terminal NEXT of the shift register is at the high-level, the output signal of the scan signal output terminal OUT may be at the low-level. Accordingly, the shift register may also be able to drive a pixel circuit with two different phases of scan signal terminals. Obviously, in each output time period, the shift signal output terminal NEXT and the scan signal output terminal OUT of the shift register may always output voltage signals with opposite phases, which may be suitable for driving any pixel circuit that can receive two different phases of scan signals.

The above is the overall structure of the shift register provided by the present disclosure. The specific structure and working principle of the shift register provided by the embodiments of the present disclosure will be explained in the following several embodiments.

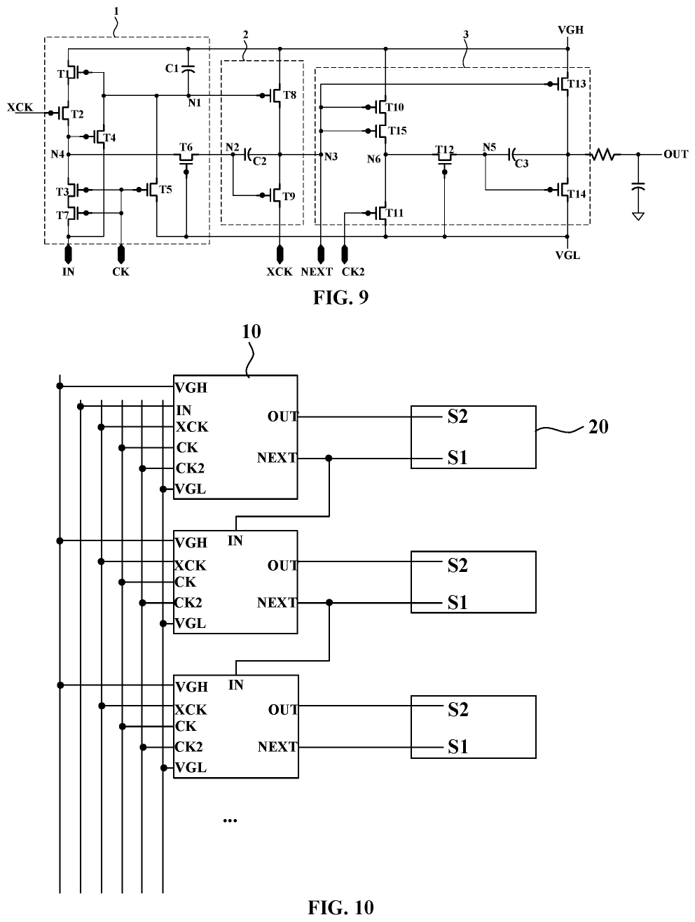

FIG. 9 illustrates another exemplary shift register consistent with various disclosed embodiments of the present disclosure. As shown in FIG. 9, in one embodiment, the input circuit 1 of the shift register may further include a seventh switch T7. The control terminal of the seventh switch T7 may be electrically connected to the second clock signal terminal CK. The seventh switch T7 may be coupled between the shift signal input terminal IN and the input terminal of the third switch T3. Further, the invert output circuit 3 of the shift register may include a fifteenth switch T15. The control terminal of the fifteenth switch T15 may be electrically connected to the third node N3. The fifteenth switch T15 may be coupled between the output terminal of the tenth switch T10 and the input terminal of the twelfth switch T12.

In one embodiment, the third switch T3, the seventh switch T7, the tenth switch T10 and the fifteenth switch T15 may all be single-gate transistors. The two single-gate transistors (switches) T3 and T7 of the input circuit 1 may be arranged in series, which may stabilize the potential of the fourth node N4, prevent leakage, and improve the electrical stability of the shift register. The two single-gate transistors (switches) T10 and T15 in the invert output circuit 3 may be arranged in series to stabilize the voltage of the sixth node N6, prevent leakage, and improve the electrical stability of the shift register.

Further, in one embodiment, the invert output circuit 3 may also include a fourth capacitor C4 and a first resistor R1. The first resistor R1 may be coupled between the scan signal output terminal OUT and the third capacitor C3. The first plate of the fourth capacitor C4 may be electrically connected to the scan signal output terminal OUT, and the second plate of the fourth capacitor C4 may be grounded. The fourth capacitor C4 and the first resistor R1 may form an RC circuit, which may filter the signal output to the scan signal output terminal OUT such that the scan signal output terminal OUT may stably output a low-level signal VGL or a high-level signal VGH.

Thus, the shift register provided in the present disclosure may realize low-level and high-level signal shift, and may have a stable output.

The present disclosure also provides a shift register circuit. FIG. 10 illustrates an exemplary shift register circuit consistent with various disclosed embodiments of the present disclosure. As shown in FIG. 10, the shift register circuit may include a multi-stage cascaded shift registers 10. The shift registers 10 may be the disclosed shift registers as described in any of the above embodiments, or other appropriate shift registers. In the structure, the shift signal output terminal NEXT of an upper level shift register 10 may be connected to the shift signal input terminal IN of a lower level shift register 10.

As shown in FIG. 10, one level shift register 10 may drive a row of pixel circuits 20. The pixel circuit 20 may include a first scan terminal and a second scan terminal. The first scan line S1 may be electrically connected to a first scan terminal of the corresponding row of pixel circuits 20, and the second scan line S2 may be electrically connected to a second scan terminal of the corresponding row of pixel circuits 20. Each pixel circuit may include a first scan terminal and a second scan terminal. A first scan line S1 driven by the one level shift register 10 may be electrically connected to the first scan terminal of each pixel circuit in the corresponding row. A second scan line S2 driven by the one level shift register 10 may be electrically connected to the second scan terminal of each pixel circuit in the corresponding row. The shift register 10 may provide two scan signals of opposite phases to each pixel circuit.

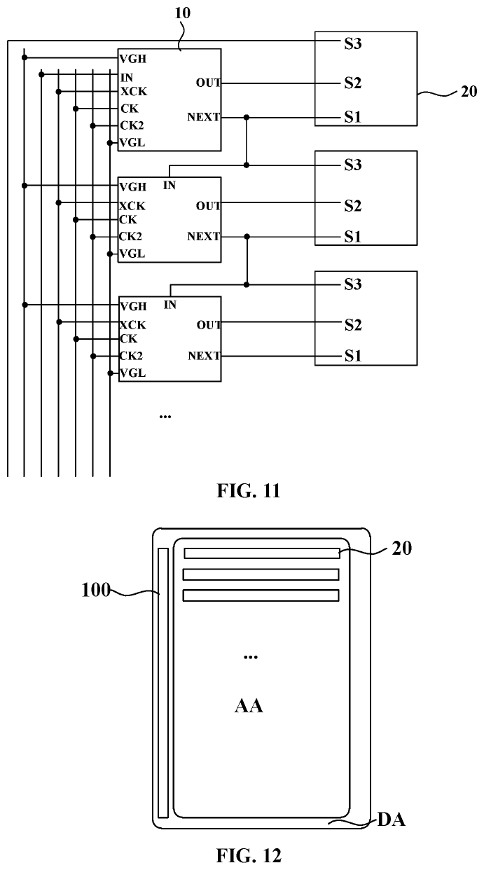

FIG. 11 illustrates another exemplary shift register circuit consistent with various disclosed embodiments of the present disclosure. As shown in FIG. 11, in one embodiment, one level shift register 10 may also drive a next row of pixel circuits 20 corresponding to a next level shift register 20, and the shift signal output terminal NEXT of the trigger output circuit may also be electrically connected to a third scan line S3. The pixel circuit may further include a third scan terminal. The third scan line S3 of the shift register 10 may be electrically connected to the third scan terminal of the pixel circuit 20 of the next row. For a row of pixel circuits 20 driven by the first level shift register 10 in the shift register circuit, the scan signal of the third scan terminal of the pixel circuit can be directly output by a driving chip (not shown).

The shift register circuit provided in the present disclosure may be able to drive any pixel circuit that receives two scan signals of opposite phases, without limiting the structure of the pixel circuit. For different pixel circuit structures, the connection modes of the shift register circuit and the pixel circuit may also be different, and may not be limited to those shown in FIG. 10 or FIG. 11. Further, a display panel may include a plurality of shift register circuits connected in parallel; and one pixel circuit may be electrically connected to the shift registers in the plurality of shift register circuits, and the configuration of the shift registers and the shift register circuits are not limited to those shown in FIG. 10 or FIG. 11.

In one embodiment, in any output period, the shift signal output terminal NEXT and the scan signal output terminal OUT of the shift register may always output voltage signals with opposite phases, which may be suitable for driving any pixel circuit that may receive two different phases of scan signals to realize high-level voltage and level voltage shift.

Further, the present disclosure provides a display panel. FIG. 12 illustrates a display panel consistent with various disclosed embodiments of the present disclosure. As shown in FIG. 12, the display panel may include a display area AA and a non-display area DA. The display area AA may include a plurality row of pixel circuits 20, and the non-display area DA may include multi-level cascaded shift registers. One stage shift register may be used to drive at least one row of pixel circuits 20. The shift register may include a shift signal output terminal and a scan signal output terminal. The pixel circuit may include a first scan terminal and a second scan terminal. The shift signal output terminal of the shift register and the first scan terminal of the corresponding row of pixel circuits may be connected through the first scan line, and the scan output terminal of the shift register and the second scan terminal of the corresponding row of pixel circuits may be connected through the second scan line.

In one embodiment, the multi-level cascaded shift registers may form at least one shift register circuit 100, and the shift register circuit 100 may be disposed in the non-display area DA. In the display panel provided by present disclosure, the shift signal output terminal NEXT and the scan signal output terminal OUT of the shift register may always output voltage signals of opposite phases, which may be suitable for driving any pixel circuit that may receive two scan signals of different phases to realize low-level and low-level shifts.

The pixel circuit may include switch transistors. The switch transistors may be N-type transistors using oxide as the active layer. The oxide may be indium gallium zinc oxide (IGZO), etc.

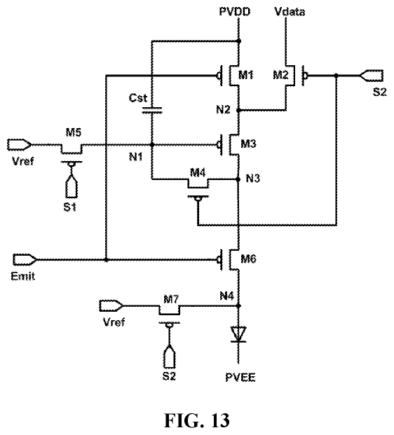

FIG. 13 is a schematic diagram of an existing pixel circuit, and the transistors of the pixel circuit are all PMOS transistors. The main manufacturing process of PMOS transistors is a low-temperature polysilicon (LTPS) technology. The switching transistors M4 and M5 that are PMOS transistors formed by the LTPS technology may have large leakage currents, and the storage capacitor Cst may also have a leakage current, which cannot meet the low-frequency display image quality requirements, such as 1-5 Hz. Thus, the frame holding situation may be worse at 1 Hz. The switch transistors M4 and/or M5 electrically connected to the first node N1 in FIG. 13 may be replaced with N-type transistors using oxide as the active layer. Using the N-type transistors having the oxide as the active layer may reduce the leakage current of the switching transistors and realize low frequency display. The N-type transistors may be turned on by a high-level scan signal, and the pixel circuit may also include a PMOS transistor formed by the LTPS technology, which may be turned on by a low-level scan signal, and may be driven by the shift register circuit as shown in FIG. 10. Accordingly, the low frequency display and high-level and high-level scan signal drive may be realized.

The display panel may be an organic light emitting display panel. The type of the display panel is not limited according to various embodiments of the present disclosure.

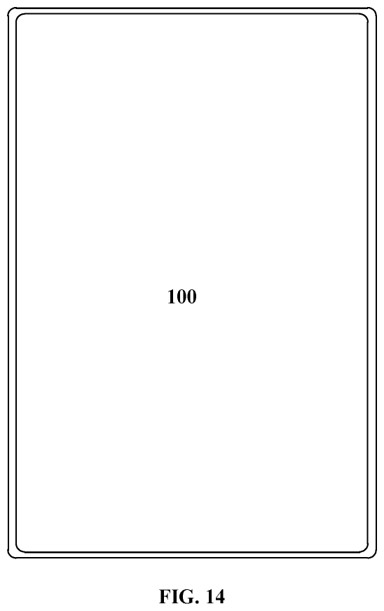

Further, the present disclosure provides an electronic device. FIG. 14 illustrates an exemplary electronic device consistent with various disclosed embodiments of the present disclosure. As shown in FIG. 14, the electronic device may include the display panel described in any of the above embodiments, or other appropriate display panel. The electronic device 100 may be a smart phone, or others.

Thus, the present disclosed shift register may transmit different voltage signals at same time in each output time period. In particular, it may be able to transmit both a low-level signal and a high-level signal at the same time. Thus, the shift register may be suitable for driving any pixel circuit which receives two different signals of different phases. The disclosed shift register circuit, the disclosed display panel and the disclosed electronic device which have the disclosed shift register may have at least the benefits of the disclosed shift register.

The description of the disclosed embodiments is provided to illustrate the present disclosure to those skilled in the art. Various modifications to these embodiments will be readily apparent to those skilled in the art, and the generic principles defined herein may be applied to other embodiments without departing from the spirit or scope of the disclosure. Thus, the present disclosure is not intended to be limited to the embodiments shown herein but is to be accorded the widest scope consistent with the principles and novel features disclosed herein.

1. A shift register, comprising:
an input circuit, including a first control terminal electrically connected to a first clock signal terminal of the shift register; a second control terminal electrically connected to a second clock signal terminal of the shift register, wherein a shift signal input terminal of the shift register is electrically connected to a shift signal output terminal of an upper-level shift register; a first signal input terminal electrically connected to a first power source terminal of the shift register; a second signal input terminal electrically connected to a second power source terminal of the shift register; and a first output terminal electrically connected to a first node and a second output terminal electrically connected to a second node, to control potentials of the first node and the second node;
a trigger output circuit, including a third signal input terminal electrically connected to the first power source terminal, a fourth signal input terminal electrically connected to the first clock signal terminal, a third control terminal electrically connected to the first node, a fourth control terminal electrically connected to the second node, and a shift signal output terminal electrically connected to a third node, a first scan line and a shift signal input terminal of a lower-level shift register, respectively; and
an invert output circuit, including a fifth control terminal electrically connected to the third node, a sixth control terminal of a transistor physically connected to a third clock signal terminal, a fifth signal input terminal electrically connected to the first power source terminal, a sixth signal input terminal of the transistor electrically connected to the second power source terminal, and a scan signal output terminal electrically connected to a second scan line;
wherein the input circuit is configured to control the potentials of the first node and the second node to drive the trigger output terminal to output a first voltage signal to the first scan line and to drive the invert output circuit to output a second voltage signal to the second scan line; and the first voltage signal is different from the second voltage signal.

2. The shift register according to claim 1, wherein:
one level shift register drives a row of pixel circuits;
the row of pixel circuits includes a first scan terminal and a second scan terminal;
the first scan line is electrically connected to the first scan terminal of a corresponding row of pixel circuits; and
the second scan line is electrically connected to the second scan terminal of a corresponding row of pixel circuits.

3. The shift register according to claim 2, wherein:
the one level shift register also drives a next row of pixel circuits corresponding to a lower-level shift register;
the shift signal output terminal of the trigger output terminal is also electrically connected to a third scan line;
the next row of pixel circuits also includes a third scan terminal; and
the third scan line of the shift register is electrically connected to the third scan terminal of the next row of pixel circuits.

4. The shift register according to claim 1, wherein:
phases of the first voltage signal and the second voltage signal are opposite.

5. The shift register according to claim 1, wherein:
the input circuit includes a first switch, a second switch, a third switch, a fourth switch, a fifth switch, a sixth switch and a first capacitor;
the first switch includes a control terminal electrically connected to the first node, an input terminal electrically connected to the first power source terminal, and an output terminal electrically connected to an input terminal of the second switch;
the second switch incudes a control terminal electrically connected to the first clock signal terminal, and an output terminal is electrically connected to a control terminal of the fourth switch;
the fourth switch includes an input terminal electrically connected to the shift signal input terminal, and an output terminal electrically connected to the first node;
the third switch includes a control terminal electrically connected to the second clock signal terminal, an output terminal electrically connected to the control terminal of the fourth switch, an input terminal electrically connected to the shift signal input terminal,
the fifth switch includes a control terminal electrically connected to the second clock signal terminal and an input terminal electrically connected to the second power source terminal, and an output terminal electrically connected to the first node;
the sixth switch includes a control terminal electrically connected to the second power source terminal, and an input terminal electrically connected to the output terminal of the third switch, and an output terminal electrically connected to the second node; and
the first capacitor is coupled between the first power source terminal and the first node.

6. The shift register according to claim 5, wherein the input circuit further comprises:
a seventh switch, including a control terminal electrically connected to the second clock signal terminal, and being coupled between the shift signal input terminal and the input terminal of the third switch.

7. The shift register according to claim 1, wherein the trigger output terminal further comprises:
an eighth switch, including a control terminal electrically connected to the first node, an input terminal electrically connected to the first power source terminal, and an output terminal electrically connected to the shift signal output terminal;
a ninth switch, including a control terminal electrically connected to the second node, an input terminal electrically connected to the first clock signal terminal, and an output terminal electrically connected to the shift signal output terminal; and
a second capacitor, coupled between the second node and the shift signal output terminal.

8. The shift register according to claim 1, wherein the invert output circuit further comprises:
a tenth switch, including a control terminal electrically connected to the third node, an input terminal electrically connected to the first power source terminal, and an output terminal electrically connected to an input terminal of a twelfth switch; wherein the transistor includes an eleventh switch, including an output terminal electrically connected to the input terminal of the twelfth switch;
a twelfth switch, including a control terminal electrically connected to the second power source terminal, and an output terminal electrically connected to a control terminal of a fourteenth switch;
a thirteenth switch, including a control terminal electrically connected to the third node, an input terminal electrically connected to the first power source terminal, and an output terminal electrically connected to the scan signal output terminal; and
a fourteenth switch, an input terminal electrically connected to the second power source terminal, and an output terminal electrically connected to the scan signal output terminal; and
a third capacitor, coupled between the control terminal of the fourteenth switch and the scan signal output terminal.

9. The shift register according to claim 8, wherein the invert output circuit further includes:
a fifteenth switch, including a control terminal electrically connected to the third node, and being coupled between the output terminal of the tenth switch and the input terminal of the twelfth switch.

10. The shift register according to claim 8, wherein the invert output circuit further comprises:
a fourth capacitor, including a first plate electrically connected to the scan signal output terminal, and a second plate being grounded; and
a first resistor, coupled between the scan signal output terminal and the third capacitor.

11. The shift register according to claim 5, wherein:
each switch includes a PMOS transistor.

12. The shift register according to claim 1, wherein:
the first power source terminal is a high-level signal terminal; and
the second power source terminal is a low-level signal terminal.

13. A shift register circuit, comprising:
a plurality of multi-level cascaded shift registers,
wherein each shift register of the plurality of multi-level cascaded shift registers includes:
an input circuit, including a first control terminal electrically connected to a first clock signal terminal of the shift register; a second control terminal electrically connected to a second clock signal terminal of the shift register, wherein a shift signal input terminal of the shift register is electrically connected to a shift signal output terminal of an upper-level shift register; a first signal input terminal electrically connected to a first power source terminal of the shift register; a second signal input terminal electrically connected to a second power source terminal of the shift register; and a first output terminal electrically connected to a first node and a second output terminal electrically connected to a second node, to control potentials of the first node and the second node;
a trigger output circuit, including a third signal input terminal electrically connected to the first power source terminal, a fourth signal input terminal electrically connected to the first clock signal terminal, a third control terminal electrically connected to the first node, a fourth control terminal electrically connected to the second node, and a shift signal output terminal electrically connected to a third node, a first scan line and a shift signal input terminal of a lower-level shift register, respectively; and
an invert output circuit, including a fifth control terminal electrically connected to the third node, a sixth control terminal of a transistor physically connected to a third clock signal terminal, a fifth signal input terminal electrically connected to the first power source terminal, a sixth signal input terminal of the transistor electrically connected to the second power source terminal, and a scan signal output terminal electrically connected to a second scan line;
wherein the input circuit is configured to control the potentials of the first node and the second node to drive the trigger output terminal to output a first voltage signal to the first scan line and to drive the invert output circuit to output a second voltage signal to the second scan line; and the first voltage signal is different from the second voltage signal.

14. A display panel, comprising:
a display area; and
a non-display area,
wherein:
the display area includes a plurality rows of pixel circuits;
the non-display area includes a plurality of multi-level cascaded shift registers, wherein each shift register at different levels of the plurality of multi-level cascaded shift registers has a same configuration with a first clock signal terminal, a second clock signal terminal, and a third clock signal terminal;
one level shift register is configured to drive at least one row of the plurality row of pixel circuits;
each of the plurality of multi-level cascaded shift registers includes a shift signal output terminal and a scan signal output terminal;
each pixel circuit of the plurality rows of pixel circuits includes a first scan terminal and a second scan terminal;
the shift signal output terminal of each of the plurality of multi-level cascaded shift registers is connected to the first scan terminal of a corresponding row of pixel circuits by a first scan line; and
the scan signal output terminal of each of the plurality of multi-level cascaded shift registers is connected to the second scan terminal of a corresponding row of pixel circuits by a second scan line.

15. The display panel according to claim 14, wherein each shift register of the plurality of multi-level cascaded shift registers comprising:
an input circuit, including a first control terminal electrically connected to a first clock signal terminal of the shift register; a second control terminal electrically connected to a second clock signal terminal of the shift register, wherein a shift signal input terminal of the shift register is electrically connected to a shift signal output terminal of an upper-level shift register; a first signal input terminal electrically connected to a first power source terminal of the shift register; a second signal input terminal electrically connected to a second power source terminal of the shift register; and a first output terminal electrically connected to a first node and a second output terminal electrically connected to a second node, to control potentials of the first node and the second node;
a trigger output circuit, including a third signal input terminal electrically connected to the first power source terminal, a fourth signal input terminal electrically connected to the first clock signal terminal, a third control terminal electrically connected to the first node, a fourth control terminal electrically connected to the second node, and a shift signal output terminal electrically connected to a third node, a first scan line and a shift signal input terminal of a lower-level shift register, respectively; and
an invert output circuit, including a fifth control terminal electrically connected to the third node, a sixth control terminal of a transistor electrically connected to a third clock signal terminal, a fifth signal input terminal electrically connected to the first power source terminal, a sixth signal input terminal of the transistor electrically connected to the second power source terminal, and a scan signal output terminal electrically connected to a second scan line
wherein the input circuit is configured to control the potentials of the first node and the second node to drive the trigger output terminal to output a first voltage signal to the first scan line and to drive the invert output circuit to output a second voltage signal to the second scan line; and the first voltage signal is different from the second voltage signal.

16. The display panel according to claim 14, wherein:
each pixel circuit of the plurality row of pixel circuits includes a switch transistor; and
the switch transistor is an N-type transistor having an active layer made of oxide.

17. The display panel according to claim 14, wherein:
the display panel includes an organic light-emitting display panel.

18. An electronic device, comprising the display panel according to claim 14.

19. The electronic device according to claim 18, wherein:
one level shift register drives a row of pixel circuits;
the row of pixel circuits includes a first scan terminal and a second scan terminal;
the first scan line is electrically connected to the first scan terminal of a corresponding row of pixel circuits and
the second scan line is electrically connected to the second scan terminal of a corresponding row of pixel circuits.

20. The electronic device according to claim 19, wherein:
the one level shift register also drives a next row of pixel circuits corresponding to a lower level shift register;
the shift signal output terminal is also electrically connected to a third scan line;
the next row of pixel circuits also includes a third scan terminal; and
the third scan line of the shift register is electrically connected to the third scan terminal of the next row of pixel circuits.
